(19) United States
(12) Patent Application Publication
(10) Pub. No.: US 2016/0026524 A1
(43) Pub. Date: Jan. 28, 2016

(54) MEMORY DEVICE

(71) Applicant: KABUSHIKI KAISHA TOSHIBA, Tokyo (JP)

(72) Inventor: Katsuhiko HOYA, Yokohama Kanagawa (JP)

(73) Assignee: KABUSHIKI KAISHA TOSHIBA, Tokyo (JP)

(21) Appl. No.: 14/610,638

(22) Filed: Jan. 30, 2015

Related U.S. Application Data
(60) Provisional application No. 62/029,095, filed on Jul. 25, 2014.

(51) Int. Cl. G06F 11/10; G11C 7/06; G11C 7/12; G11C 11/02

(52) U.S. Cl. CPC G06F 11/1008; G11C 11/02; G11C 7/06; G11C 7/12

(57) ABSTRACT

A memory device includes memory elements and a controller. The memory controller executes a process including a first section and a second section in response to a refresh command, detects an error of data stored in the memory elements in the first section, and writes correct data in a memory element storing data with the detected error in a second section, the second section being variable in accordance with a time to write the correct data.

### CROSS-REFERENCE TO RELATED APPLICATIONS

This application claims the benefit of U.S. Provisional Application No. 62/029,095, filed Jul. 25, 2014, the entire contents of which are incorporated herein by reference.

### FIELD

Embodiments relates to a memory device.

### BACKGROUND

Memory devices store data in accordance with instructions. The stored data, however, may unintentionally change into erroneous data. Error correction techniques for correcting such errors are known. A circuit for correcting errors may be provided in a memory device.

### BRIEF DESCRIPTION OF THE DRAWINGS

FIG. 1 illustrates functional blocks of a memory device of a first embodiment;

FIG. 2 illustrates functional blocks of an error correction unit of the first embodiment;

FIG. 3 illustrates the operation in the first embodiment over time;

FIG. 4 illustrates the operation in a second embodiment over time;

FIG. 5 illustrates the operation in a third embodiment over time;

FIG. 6 illustrates functional blocks of part of the column controller;

FIG. 7 illustrates division of a refresh execution unit;

FIG. 8 illustrates the connection line in detail;

FIG. 9 illustrates signals transmitted and received between a memory device and a memory controller during data reads in accordance with a fourth embodiment; and

FIG. 10 illustrates signals transmitted and received between a memory device and a memory controller during a data write in accordance with a fifth embodiment.

### DETAILED DESCRIPTION

According to one embodiment, a memory device comprising: memory elements; and a controller which executes a process including a first section and a second section in response to a refresh command, detects an error of data stored in the memory elements in the first section, and writes correct data in a memory element storing data with the detected error in a second section, the second section being variable in accordance with a time to write the correct data.

As described, some types of memory devices include an error correction unit as well as a data storage unit. The data storage unit is a main section of a memory device, and stores data received from outside the memory device. The error correction unit uses error correction codes (ECCs) to correct errors of the data in the storage section, for example. For example, the memory device receives a command instructing to store, or write, data, and data to be written from outside. The data to be written, or write data, is received by the error correction unit. The error correction unit divides the received data into segments of a predetermined size, and uses the segments to generate error correction codes in accordance with a predetermined rule. The data storage unit then receives the segments of the write data and the error correction codes generated for the segments of the write data from the error correction unit. These sets of the substantial write-data segment and the corresponding error correction code are written in memory cells by the data storage unit.

When the memory device is instructed to read stored data, the data storage unit reads data including the instructed data. The read data includes the substantial data instructed to be read, and the corresponding error correction code. The read data is input to the error correction unit, which executes an error correction operation to the received data. The error correction unit corrects, if any, errors in the substantial data, and outputs error-corrected substantial data.

The memory devices with the error correction unit may support the technique of read modified writes. The read modify write refers to writing, upon detection of error bits in data from the data storage unit by the error correction unit, correct data in the memory cells storing the error bits. Using such a write-back technique can prevent the count of memory cells storing error bits from accumulating to suppress the occurrence of read errors. The write back, however, leads to an increased time of a read cycle of the memory device. In general, memory devices need a particular time from a reception of a read command to completion of the read, and this time is the read cycle. In memory devices which support the write backs, the read cycle includes a time for the write backs. Including the write back in the read cycle is effective for a case with frequent occurrences of the write backs. In contrast, if the write backs do not occur frequently, the time for the write backs will unnecessarily increase the read time. This may deteriorate convenience of the memory devices.

Embodiments will now be described with reference to figures. In the following description, identical signs may be given to components which have substantially the same functions and details, and a repeated description may be omitted. Moreover, an entire description for a particular embodiment also applies as a description for another embodiment unless stated otherwise. Embodiments are used only for the purpose of describing a device and/or method for implementing the technical idea of this embodiment.

### First Embodiment

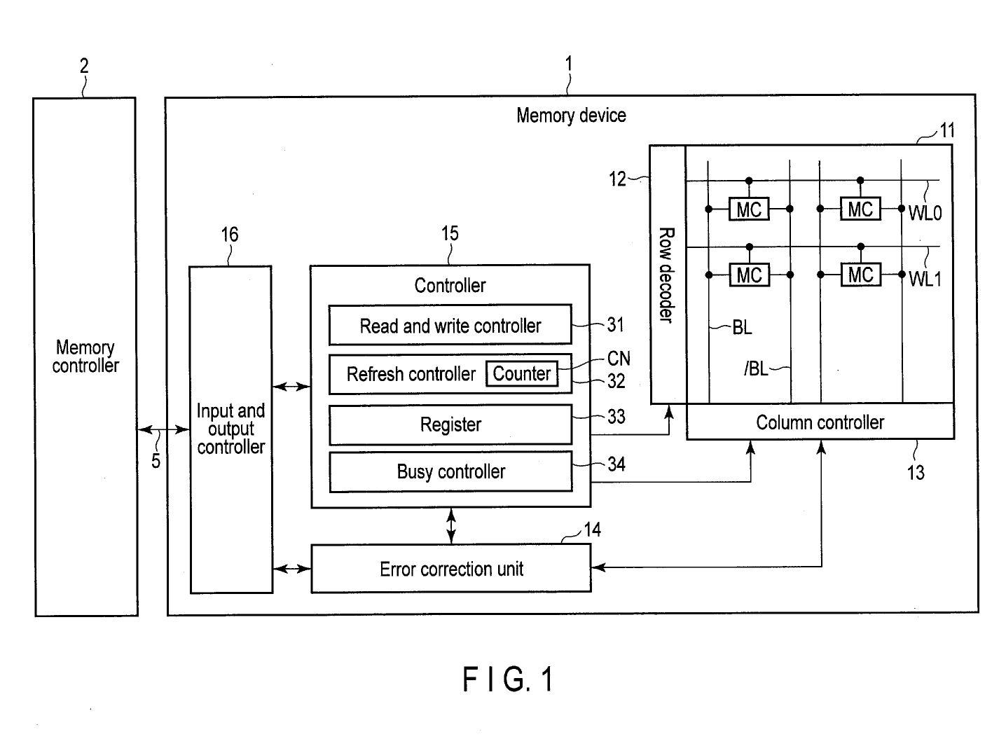

FIG. 1 illustrates functional blocks of a memory device of the first embodiment. FIG. 1 also illustrates a memory controller 2 which communicates with the memory device 1. It is not necessary that each functional block is distinguished as in the following examples. For example, some of functions may be implemented by functional blocks different from those illustrated below.

The memory device 1 is formed as a single chip. The memory device 1 is configured to store data by any known scheme. Specifically, the memory device 1 is a dynamic RAM (DRAM), a magnetoresistive RAM (MRAM), a resistive RAM (ReRAM), or a phase change RAM (PCRAM), for example. In accordance with the type of RAM, components and connections in sections of the memory device 1 known to persons skilled in the art differ from each other. For this reason, FIG. 1 illustrates an example of components generally widely included in RAMs. The memory device 1, however, can have functional blocks different from those in FIG. 1 in accordance with the type of RAM, and the functional blocks included in the memory device 1 are not limited to the FIG. 1 example.

The memory device 1 is communicatively coupled to the memory controller 2 by a connection line 5. The connection line 5 includes a power line, a data bus, and a command line, etc., for example. The memory controller 2 supplies various commands to the memory device 1 to instruct operations to the memory device 1, such as a read of data from and a write of data to the memory device 1. The memory controller 2 supplies a read command and a read address to the memory device 1 to read data from the memory device 1. The read address is an address of part of the memory device's memory area storing the data which the memory controller wishes to read. The memory controller 2 also supplies a write command, a write address and write-data to the memory device 1 to write the data in the memory device 1. The write data is data which the memory controller 2 wishes to store in the memory device 1. The write address is an address of part of the memory device's memory area in which the memory controller 2 wishes to store the write data.

The memory controller 2 receives instructions from another device, for example, a host device, and executes the received instructions. In order to implement such a function of the memory controller 2, the memory controller 2 includes components, such as a processor, a central processing unit (CPU), a read only memory (ROM), and a random access memory (RAM), for example. The memory controller 2 executes various operations when a program stored in the ROM is executed by the processor, for example.

The memory device 1 includes components, such as a memory cell array 11, a row decoder 12, a column controller 13, an error correction unit 14, a controller 15, and an input and output controller 16. The memory cell array 11 includes memory cells MC. The details of the memory cell array 11 vary in accordance with the type of the memory device 1. For example, for a case of the memory device 1 being the MRAM, the memory cell array 11 includes memory cells MC configured to use the magnetoresistive effect to store data in the memory cells MC, and includes the memory cells MC arranged in the form of a matrix. The memory cell array 11 also includes bit lines BL and /BL, and word lines WL. Each memory cell MC is coupled to bit lines BL and /BL and a word line WL.

A memory cell MC of the MRAM includes a magnetic tunnel junction (MTJ) element and a select transistor. The MTJ element includes an MTJ and includes two magnetic layers and a nonmagnetic layer therebetween. The first magnetic layer has an invariable magnetization orientation, or a magnetic anisotropy direction, and the second magnetic layer has a variable magnetization orientation. When the magnetization orientations of the two magnetic layers are parallel and anti-parallel, the MTJ element exhibits the minimum and maximum resistances, respectively. The states exhibiting the two switchable different resistances are assigned to data of two values, respectively. When a write current flows from the first magnetic layer to the second magnetic layer, the magnetization orientations of the two magnetic layers become parallel. When a write current flows from the second magnetic layer to the first magnetic layer, the magnetization orientations of the two magnetic layers become anti-parallel.

A select transistor is, for example, an n-channel metal oxide semiconductor field effect transistor (MOSFET).

An MTJ element is coupled between a bit line and one end of a select transistor. A select transistor is coupled to a word line WL at the gate, and to a bit line /BL at the other end.

The memory cell array 11 may be divided into more than one unit. The units may be referred to as banks, for example. Access to the memory cell array 11 includes identification of a bank to be accessed.

The row decoder 12 is coupled to the word lines WL. The row decoder 12 selects one of the word lines WL in accordance with a row address.

The column controller 13 is coupled to the bit-line pairs BL and /BL. During a write, the column controller 13 selects one of the bit-line pairs in accordance with a column address, and conducts a write current to a selected memory cell through the selected bit-line pair to write data in the selected memory cell. During a read, the column controller 13 selects one of the bit-line pairs in accordance with the column address, and reads data from the selected bit-line pair. In order to execute such operations, the column controller 13 includes a column decoder, a column selector, a sense amplifier, a write driver, etc.

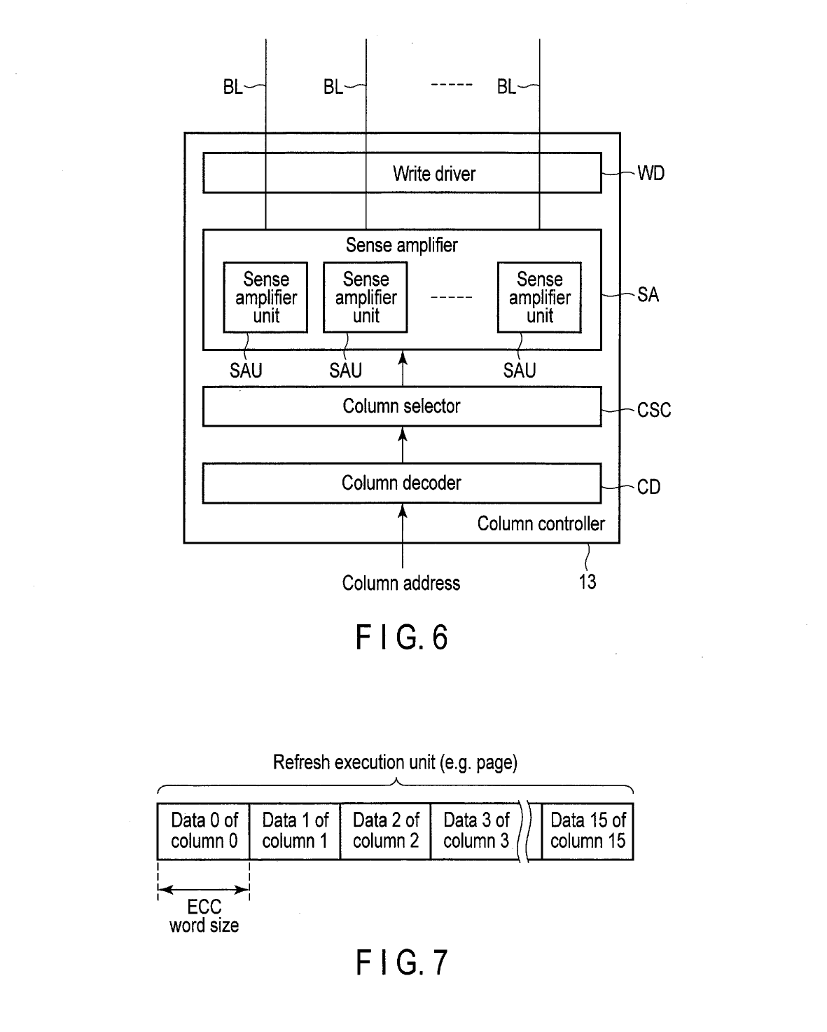

FIG. 6 illustrates functional blocks of part of the column controller 13. The sense amplifier SA includes sense amplifier units SAU. The sense amplifier SA includes as many sense amplifier units as the bit lines BL (or bit lines /BL), for example. Different sense amplifier units SAU are coupled to different bit lines BL, i.e., the sense amplifier units SAU and the bit lines BL are coupled one-to-one. Each sense amplifier unit SAU amplifies the potential on the connected bit line BL. During data reads, one or more of all the sense amplifier units SAU are selected by the column selector CSC. The column selector CSC receives a column address from the column decoder CD, and selects a column in accordance with the column address. One column corresponds to a set of bit lines BL. The write driver WD supplies write currents to the bit lines BL and /BL.

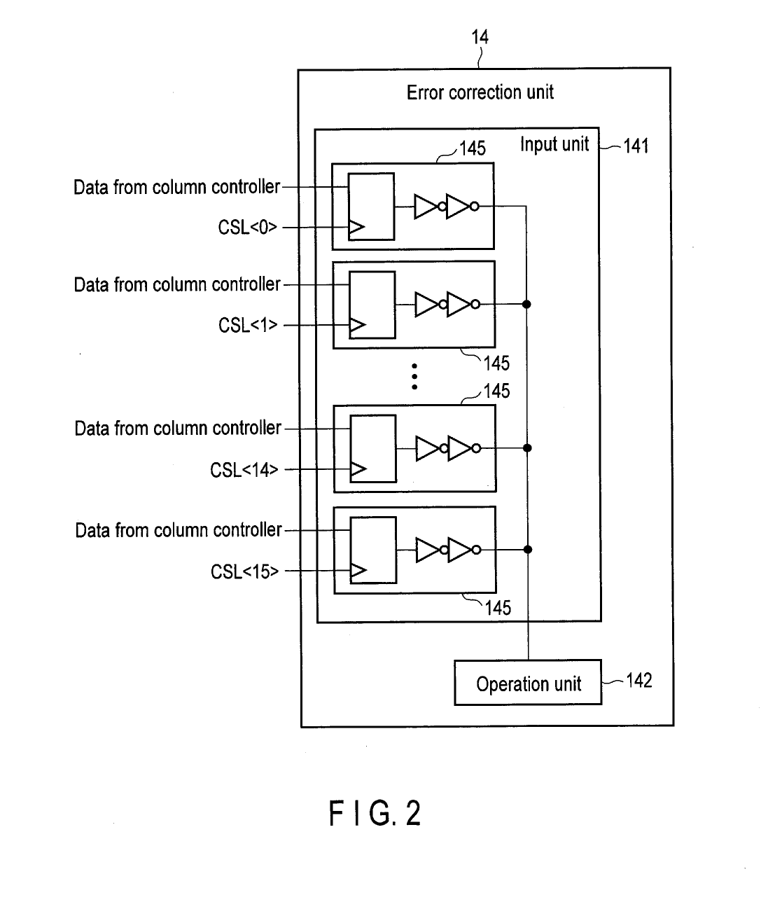

The error correction unit 14 uses error correction codes to correct errors of data stored in the memory device 1. More specifically, the error correction unit 14 includes an input unit 141 and an operation unit 142 as illustrated in FIG. 2. The input unit 141 receives data whose errors will be corrected. The error-correction-target data is write data from the memory controller 2 in data writes, and is read data from the memory cell array 11 in data reads. The input unit 141 divides received data into segments of a predetermined size. The size of each segment is equal to the size of the unit to which the operation unit 142 executes operations for correcting errors. The segments of the same size as the unit of the operation for error correction are referred to as ECC words, for example. For dividing data, the input unit 141 includes units 145.

Each unit 145 receives data (or, a string of bits of 1 or 0) of the same number of bits as that of an ECC word. The data of the units 145 do not overlap mutually. Each unit 145 receives one of control signals. FIG. 2 relates to an example of sixteen units 145 and control signals CSL <0> to CSL <15> for respective units 145. Each unit 145 outputs the received data to the operation unit 142 when it receives the corresponding asserted control signal.

The operation unit 142 receives a segment of write date of the same size as the ECC word, generates an error correction code or parity bits in units of write data segments in accordance with the rule for generating error correction codes, and outputs a set of the generated write data segments and parity bits. The set of a write data segment and corresponding parity bits are written in particular memory cells MC by control of the controller 15.

The operation unit 142 also receives a segment of read data of the same size as the ECC word. This read data segment includes substantial data and the corresponding parity bits. When the operation unit 142 receives a read data segment, it uses the parity bits to detect an error in the substantial data of the read data segment, corrects the detected error, and outputs the error-corrected substantial data.

The error correction unit 14 can correct errors of the number of bits determined in accordance with the rule for generating the error correction codes in a single ECC word. For example, the error correction unit 14 can correct a one-bit error in a single ECC word.

Referring back to FIG. 1, the input and output controller 16 controls transmission of signals between the memory device 1 and the memory controller 2. The input and output controller 16 supplies commands and addresses from the memory controller 2 to the controller 15. Moreover, the input and output controller 16 transmits write data from the memory controller 2 to the error correction unit 14, and outputs read data from the error correction unit 14 to the memory controller 2.

The controller 15 includes components, such as a command decoder, latches, buffers, and a voltage generator, and controls other components of the memory device 1 in accordance with the received commands and addresses. More specifically, the controller 15 includes a read and write controller 31, a refresh controller 32, a register 33, and a busy controller 34.

The read and write controller 31 is part of the function of controller 15 for controlling reads and writes from and to the memory cell array 11. In accordance with received commands and addresses, the read and write controller 31 controls the row decoder 12 and the column controller 13 to read data from one or more memory cells MC specified by the addresses. The read and write controller 31 controls the row decoder 12 and the column controller 13 in accordance with received commands and addresses to write data in one or more memory cells MC specified by the addresses.

The refresh controller 32 is part of the function of controller 15 for controlling refreshes. A refresh involves a check of data stored in the memory cells, and a re-write when necessary. The busy controller 34 is part of the function of controller 15 for controlling outputting of a busy signal from the memory device 1. The busy controller 34 instructs the input and output controller 16 to output the busy signal to the memory controller 2 in accordance with received instructions.

The operation of the memory device 1 will now be described. The values of data stored in the memory cells MC may unintentionally change because of some reasons, such as the environment around the memory device 1, the properties of the memory device 1, or how the memory device 1 is used. The value which has become stored with an error may be corrected by the error correction unit 14 although the number of correctable values (i.e., bits) depends on the capability of the error correction unit 14. In accordance with this, it is thinkable to refresh data to prevent the number of errors from exceeding the capability of the error correction unit 14.

The memory controller 2 supplies a refresh command to the memory device 1 at a particular timing. The input and output controller 16 is configured to recognize the refresh command. When a refresh command is received by the memory device 1, the memory device 1 executes a refresh. The memory controller 2 issues refresh commands at a fixed interval, and is configured to issue refresh commands at variable intervals. Moreover, the memory controller 2 determines the timing to issue the refresh command, for example in accordance with various conditions. The refresh should be executed before errors beyond the capability of the error correction unit 14 occur. Therefore, the memory controller 2 executes refreshes at an interval which prevents occurrence of errors beyond the capability of the error correction unit 14. This interval is determined in advance in accordance with the properties of the memory device 1 controlled by the memory controller 2, for example. On the other hand, the memory controller may be instructed for consecutive reads and/or writes of data from the host device. In such a case, the memory controller 2 inserts refreshes among consecutive reads and/or reads so that refreshes occur at an interval shorter than the predetermined interval.

When a refresh command is received by the memory device 1, the refresh controller 32 starts a refresh. The refresh controller 32 executes refreshes in units of sets of a particular one or more of all the memory cells MC. The set of memory cells MC to which a refresh in accordance with a single refresh command is executed will be referred to as a refresh execution unit. The refresh execution unit is a page, for example. A page is particular memory cells MC, and, for example, is a set of memory cells MC read together or memory space of such a set of memory cells MC. Furthermore, a page is a set of all the memory cells MC connected to one word line or memory space of such a set of memory cells MC, and, for example, has a size of bits of the same number as the memory cells MC coupled to one word line.

The refresh controller 32 executes a refresh to a refresh execution unit whenever it receives a refresh command. The refresh controller 32 has a counter CN, for example, in order to execute refreshes for different refresh execution units. The counter CN stores the address of the refresh execution unit to which the last refresh was executed. When the refresh controller 32 receives the refresh command, it executes the refresh to the refresh execution unit of the address specified by the counter and increments the value in the counter to the address of the next refresh execution unit.

In order to execute the refresh to the specified refresh execution unit, the refresh controller 32 uses the error correction unit 14 to correct an error of the data stored in the specified refresh execution unit of a refresh target. Specifically, the refresh controller 32 reads data from the refresh execution unit of the refresh target through control of the read and write circuit 31. The refresh controller 32 then detects and corrects an error in the read data through control of the error correction unit 14. The error correction unit 14 follows the instructions from the refresh controller 32 to detect errors in units of ECC words received, corrects, if any, the errors, and outputs the correct data (error-corrected ECC words), as described above. When an error is detected and corrected, the refresh controller 32 instructs the read and write controller 31 to write a correct value in the memory cell MC having stored the error-corrected bit. When the read and write controller 31 receives the instructions, it writes, i.e., writes back, the correct data in the instructed memory cell MC.

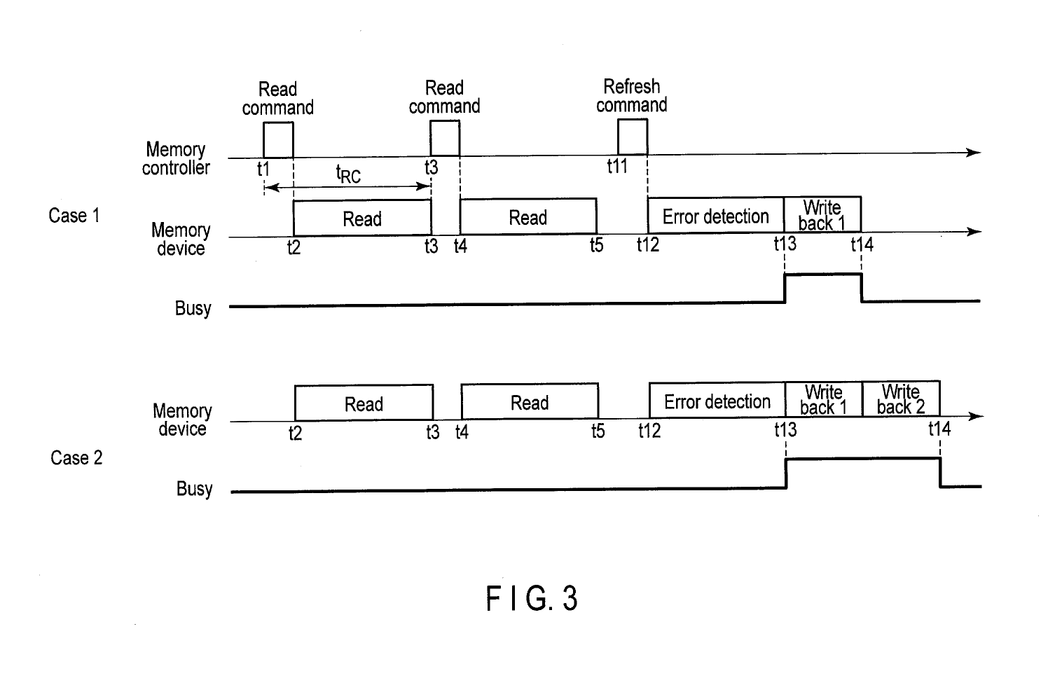

Referring to FIG. 3, the refresh of the first embodiment will be further described. FIG. 3 illustrates the operation in the first embodiment over time, and, in particular, the operation during reads and a refresh in the memory device 1. The memory controller 2 transmits a read command to the memory device 1 from time t1 as illustrated in FIG. 3. The read command includes an instruction of read, and the address of the memory cells MC of the target of read. A read command specifies a single page as a target of read, for example. Responding to receipt of the read command, the read and write controller 31 reads data from the specified memory cells MC. The data from memory cells MC goes through detection and correction of errors by the error correction unit 14, and is then transmitted to the memory controller 2 by the input and output controller 16. The read continues from time t2 to time t3. When errors are detected, the read and write controller 31 may or may not write back the correct data to the memory cells MC storing the error bits. However, since the refresh includes write back as will be described, writing back of correct data may not be included to reduce the read time.

The memory controller 2 transmits another read command to the memory device 1 from time t4. Responding to receipt of this read command, the memory device 1 reads the specified data. The read continues from time t4 to time t5. The time from receipt of a read command by the memory device 1 to the time when the memory device 1 is ready to receive the next read command is defined as the read cycle t_{RC}. The duration of the read cycle t_{RC} is determined in advance in accordance with the performance of the memory device 1. In the FIG. 3 example, between times t1 and t3 is the read cycle t_{RC}.

The memory controller 2 executes the refresh to the memory device 1 at a particular timing. To this end, the memory controller 2 transmits the refresh command to the memory device 1. The timing of issuance of the refresh command by the memory controller 2 is determined by the memory controller 2 as described above. FIG. 3 illustrates issuance of the refresh command at time t11 as an example. Time t11 follows time t5.

Responding to receipt of the refresh command, the refresh controller 32 executes the refresh to the refresh execution unit specified by the counter. The refresh triggered by a single refresh command includes two stages. The first stage includes detection of errors, and the following second stage includes write backs of correct data to the memory cell MC.

In the first stage, the refresh controller 32 controls the read and write controller 31 and the error correction unit 14 to detect errors in the refresh execution unit (for example, a page) of a refresh target. As described above, the error correction unit 14 detects errors in units of ECC words. Specifically, a refresh execution unit is divided into more than one ECC word, as illustrated in FIG. 7.

Referring back to FIG. 3, when the error correction unit 14 detects an error, it reports the error detection to the refresh controller 32. The error correction unit 14 recognizes the ECC word in which the error was detected, and stores the address information which specifies the memory cells MC storing data of the error-containing ECC word in the register 33. A set of memory cells MC corresponding to a single ECC word is hereinafter referred to as a correction-unit cell set. When the number of bits of an ECC word is equal to the number of memory cells MC specified by a single column address, the error correction unit 14 stores a single column address as the address information which specifies a correction-unit cell set. The refresh controller 32 executes the error detection and storing of address information specifying error-containing ECC words in units of ECC words until the entire refresh execution unit of a refresh target is covered. The first stage ends when the error detection and storing of address information specifying error-containing ECC words for the entire refresh execution unit is completed. The first stage continues from time 12 to time t13. During the first stage, no data is output from the memory device 1. Specifically, the read and write controller 31 does not output the data in the refresh execution unit of the refresh target from the memory device 1.

The duration of the first stage depends on the performance of the memory device 1, especially the speed of data read and error correction by the read and write controller 31 and the error correction unit 14, and, for example, the longest first stage under various conditions is determined for the memory device 1.

When the first stage ends, the refresh controller 32 executes the second stage in accordance with the results of execution of the first stage. In the second stage, the refresh controller 32 refers to one or more address information items in the register 33, specifies one or more correction-unit cell sets storing the data corresponding to the ECC words specified by these address information items, and writes back correct data in the specified correction-unit cell sets. Specifically, the refresh controller 32 uses the read and write controller 31 to read data from a single specified correction-unit cell set. The refresh controller 32 then uses the error correction unit 14 to correct the error of the read data. Furthermore, the refresh controller 32 uses the read and write controller 31 to write the error-corrected data in the correction-unit cell set having stored the pre-error-correction data. The write back may be executed only to a single memory cell MC storing the error data, or bit, of the specified correction-unit cell set.

The refresh controller 32 executes a series of error correction and write backs in units of correction-unit cell sets to all the correction-unit cell sets specified by the information in the register 33. The second stage ends when the write backs to all the specified correction-unit cell sets are completed.

The refresh controller 32 uses the busy controller 34 to keep outputting the busy signal from the input and output controller 16 from the start to end of the second stage. The output of the busy signal indicates that the memory device 1 cannot receive access from the memory controller 2. The duration of the second stage depends on the count of the correction-unit cell sets of the write back target. FIG. 3 illustrates cases 1 and 2 of write backs to one and two correction-unit cell sets, respectively. The second stage continues from time t13 to time t14 and has a variable duration, and therefore a time for completion of a single refresh varies, although the duration of the first stage is invariable as described above.

The refresh controller 32 does not execute a second stage when no error is detected in the first stage. In this case, the refresh controller 32 does not output the busy signal after the end of the first stage. Therefore, in this case, the memory device 1 can accept the following command when the first stage ends.

As described, the memory device 1 of the first embodiment recognizes the refresh command and executes the refresh when it receives the refresh command. Thus, the memory device 1 has a mechanism for triggering only the refresh. Therefore, the memory device 1 can avoid the read modified writes. This leads to a reduced read cycle t_{RC}.

Moreover, the memory device 1 searches for errors in specified memory cells MC and writes back correct data to the memory cells MC storing error bits as the refresh. For this reason, through the refresh, the count of the memory cells MC which have come to store erroneous data can be decreased. This makes errors restorable in the stage where there are few erroneous bits in the ECC words and therefore they can be corrected. Without the refresh, when the count of error bits increases in a particular ECC word to exceed the correctable number of bits in that ECC word, then this ECC word will be an area in which error bits are uncorrectable. According to the memory device 1, error bits are reset through the refresh, and accumulation of the count of error bits is avoided. The present embodiment is effective especially when the memory device 1 uses a system in which data is relatively easy to flip.

Moreover, the refresh has two stages and the first stage only includes detection of ECC words including an error bit. The detection of error bits does not depend on the count of error bits, and, therefore, the first stage ends in a predetermined period. For this reason, the period from issuance of a refresh command to completion of the first stage is also fixed, and the memory controller 2 can easily schedule the control of the memory device 1. In other words, the convenience of the memory device 1 is high. In contrast, the second stage includes the write backs of correct data to the correction-unit cell sets corresponding to the detected ECC words, and therefore the duration of a second stage varies in accordance with the count of detected ECC words. However, in general, errors are relatively rarely detected, no error is found, or, if any, an only possibility is that an error is found in only a single ECC word in a single refresh execution unit (for example, a page) at most. For this reason, the second stage is not so long, either. Thus, the total time for the refresh, i.e., the period of the busy of the memory device 1 in response to the receipt of the refresh command, does not include a write-back time, which varies in length but hardly occurs. For this reason, the read cycle can be shorter than that in the example of the write-back time being included in the read cycle.

### Second Embodiment

The memory device 1 of the second embodiment differs from the first embodiment in the operation of the refresh controller 32. Therefore, the memory device 1 of the second embodiment is the same as the first embodiment (FIG. 1) in included functional blocks. The register 33 is, however, unnecessary as will be described in the second embodiment.

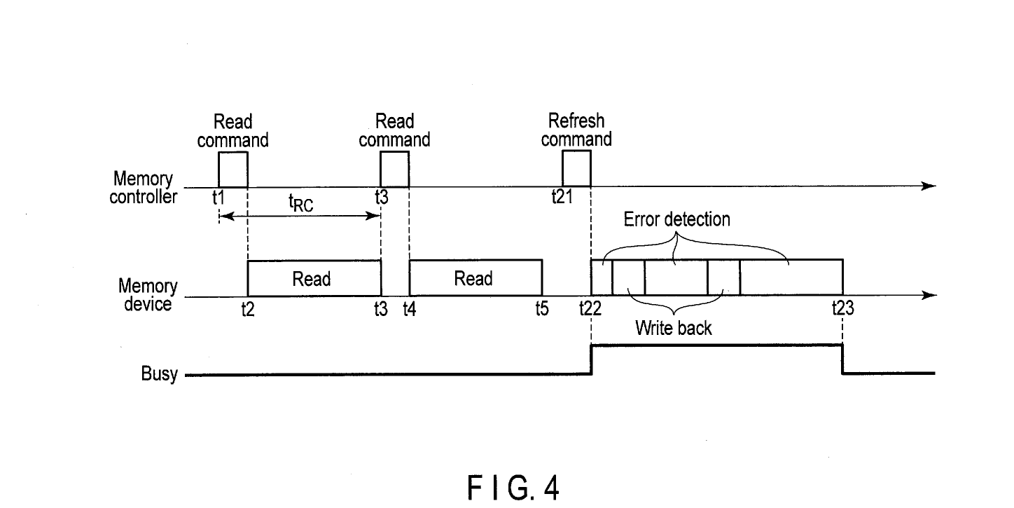

FIG. 4 illustrates the operation in the second embodiment over time. The reads are the same as those in the first embodiment and as described with reference to FIG. 3. In response to receipt of the refresh command at time t21, the memory device 1 starts the refresh. The refresh execution unit of refresh target is specified through incrementing the address of the refresh execution unit (for example, page) as in the first embodiment.

In the refresh, the refresh controller 32 uses the error correction unit 14 to detect and correct errors in the refresh execution unit of a refresh target. The detection and correction of errors are executed in units of ECC words. When the error correction unit 14 corrects an error, it reports the correction of an error to the refresh controller 32. The error correction unit 14 recognizes the ECC word in which the error was detected, and identifies the memory cells MC storing data of the error-containing ECC word, i.e., the correction-unit cell set. The error correction unit 14 then uses the read and write controller 31 to write back the correct data to the identified correction-unit cell set. When the error detection and write back of the correct data for a single ECC word are completed, the refresh controller 32 treats the next unprocessed ECC word in the refresh execution unit of refresh target as the target for the refresh. With no error detected, the refresh controller 32 does not execute the write back.

Thus, the refresh controller 32 executes the error detection and write back of the correct data in units of ECC words until the entire refresh execution unit of the refresh target is covered. When an error is detected, right after this, the refresh controller 32 executes the write back of the correct data, which eliminates the necessity of the register 33. The refresh ends when the error detection and write backs of correct data to the entire refresh execution unit of the refresh target are completed. The refresh continues from time t22 to time t23.

The refresh controller 32 uses the busy controller 34 to keep outputting the busy signal from the memory device 1 over the refresh. The time for the refresh can be shorter or longer in accordance with the existence of an error.

Thus, the memory device 1 of the second embodiment recognizes the refresh command and executes the refresh when it receives the refresh command. For this reason, the memory device 1 can have a reduced read cycle t_{RC} through avoidance of the read modified writes, and avoid accumulation of the count of error bits, as in the first embodiment. Moreover, the refresh of the second embodiment includes the write back of correct data right after detection of errors in each ECC word. For this reason, the register (register 33) for storing the addresses of the memory cells MC storing an error bit is unnecessary.

### Third Embodiment

The third embodiment is based on write backs of correct data from erroneous data with the read modified writes instead of the refreshes.

The memory device 1 of the third embodiment has functional blocks of the first embodiment (FIG. 1) without the refresh controller 32 and the register 33. However, the operation of the read and write controller 31 in the third embodiment differs from that in the first embodiment as will be described.

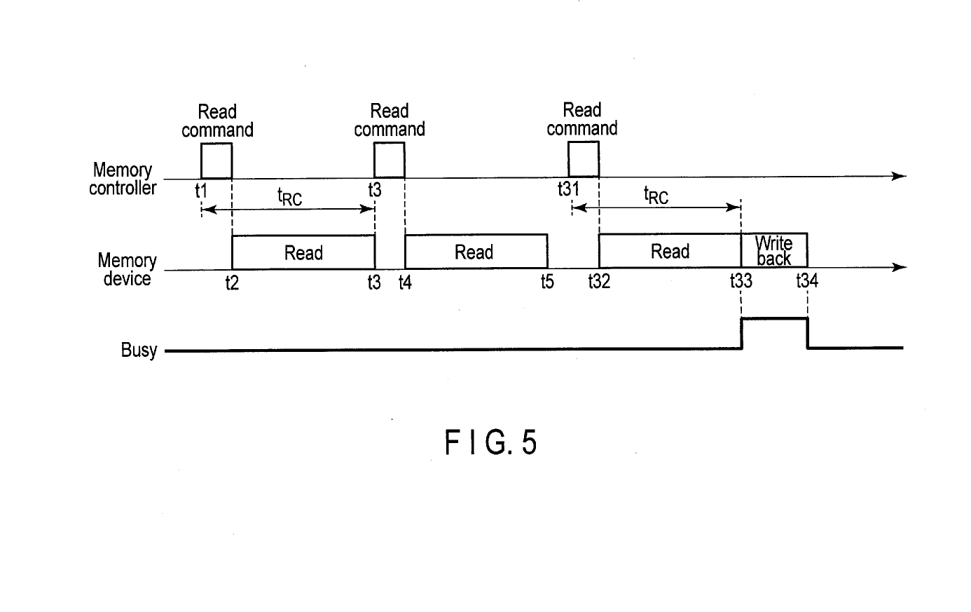

FIG. 5 illustrates the operation in the third embodiment over time. When the memory device 1 of the third embodiment receives a read command, it executes a read. The read itself is the same as the first embodiment, and is as described with reference to FIG. 3. Specifically, the read and write controller 31 uses the error correction unit 14 to detect and correct errors of the read target data. Concurrently, the error correction unit 14 maintains correct data for all read target data in the third embodiment. Specifically, the error correction unit 14 executes error detection and correction in units of ECC words, and maintains the results of the detection and correction, i.e., correct data, for all the ECC words of the entire amount of read target data. Even when no error is detected, correct data as a result of the operation for error correction is generated in the error correction unit 14. The error correction unit 14 maintains such data of the size of the error-uncorrected ECC word. The read and write controller 31 recognizes the relationships between the results of operation and corresponding ECC words.

After the read and write controller 31 completes the output of the entire amount of read target data to the memory controller 2 at time t33, it determines whether an error was included in the read target data. Specifically, the read and write controller 31 checks the results of the operation for error correction in the error correction unit 14 for the entire amount of read target data to determine whether there is an error.

When an error was detected and corrected, the read and write controller 31 identifies the memory cells MC storing data of the error-containing ECC word, i.e., a correction-unit cell set. The read and write controller 31 then writes back the correct data to all identified correction-unit cell sets. During the write back, the read and write controller 31 controls the busy controller 34 to keep outputting the busy signal from the memory device 1. The busy signal keeps being output from time t33 to completion of the write back (time t34). Also in the third embodiment, the read cycle t_{RC} does not include a time for write back as in the first and second embodiments, and the period of a write back is indicated by the busy signal. Therefore, the read cycle t_{RC} is determined in advance in accordance with the performance of the memory device 1, and is fixed. When the output of the busy signal stops, a series of reads and write backs ends, and the memory device 1 is ready to receive the next command.

Thus, according to the third embodiment, the write backs of the correct data are executed after the read, the read period including error correction is defined as the read cycle t_{RC}, and the read cycle t_{RC} does not include the period for write backs. For this reason, the read cycle is fixed and the memory controller 2 can easily schedule the control of the memory device 1. In other words, the convenience of the memory device 1 is high.

### Fourth Embodiment

The fourth embodiment relates to rules on transmission of commands between the memory device 1 and the memory controller 2, and transmission of commands and address signals for data reads. The memory device 1 is any memory device other than a DRAM, and is a nonvolatile memory device.

The memory device 1 of the fourth embodiment has the same functional blocks as those of the first embodiment (FIG. 1). Some functional blocks, however, are not used in the fourth embodiment, but used when the fourth embodiment is combined with the first embodiment.

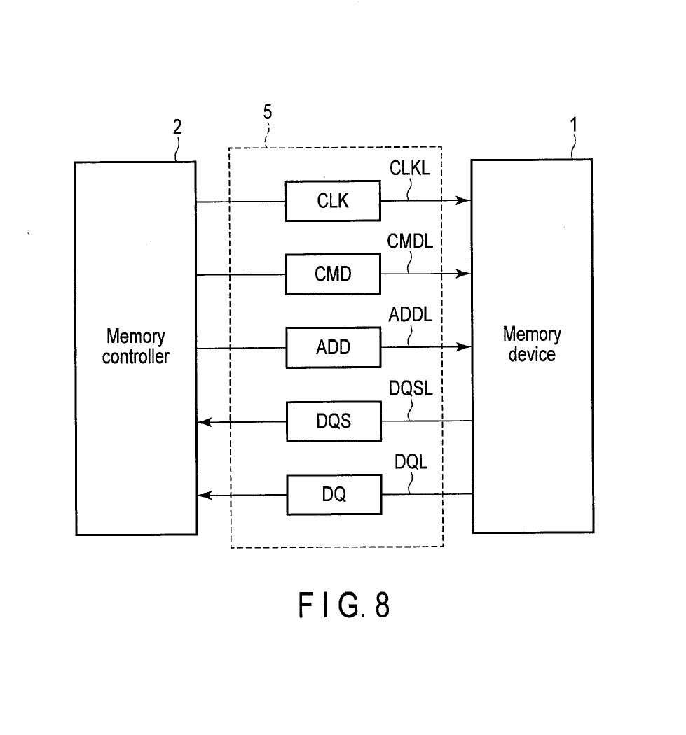

FIG. 8 illustrates the connection line 5 in detail. The connection line 5 includes a clock line CLKL, a data bus DQL, a data strobe line DQSL, a command line CMDL, and an address line ADDL. The memory controller 2 transmits a clock CLK to the memory device 1 on the clock line CLKL. Moreover, the memory controller 2 transmits commands CMD and address signals ADD on the command line CMDL and the address line ADDL, respectively.

The memory device 1 and the memory controller 2 transmits or receives data DQ on the data bus DQL, and transmits or receives a data strobe DQS on the data strobe line DQSL. The data DQ and the data strobe DQS are supplied to the memory device 1 from the memory controller 2 during data writes. In contrast, the data DQ and the data strobe DQS are supplied to the memory controller 2 from the memory device 1 during data reads. During data reads, the memory device 1 generates the data strobe DQS from the clock CLK. The data strobe DQS is a periodic signal which is alternatively made high and low, and, for example, has the same cycle as that of the clock CLK. The data strobe DQS is fixed to a level between the high and the low (or, an intermediate potential) during periods other than data transmissions and receptions, for example.

The address signals ADD include values of addresses, which include row addresses RA and/or column addresses CA. A row address RA is supplied to the row decoder 12, and specifies one of the word lines WL. When the row decoder 12 receives a row address RA, it selects the word line WL specified by the row address. A column address CA is supplied to the column controller 13, and specifies one of the columns. One column specifies sixty-four bit lines BL (and therefore sixty-four bit line pairs), for example. The column address is received by the column decoder CD (FIG. 6), which decodes the column address, and the column selector CSC operates in accordance with the decoding. The column selector CSC selects a column (or, sense amplifier units SAU) in accordance with the column address.

The command CMD instructs various operations. The instructed operations include data reads and data writes. During data reads, the read and write controller 31 controls the row decoder 12 and the column controller 13 to read data from the memory cells MC specified by the row addresses RA and column addresses CA. In contrast, during data writes, the read and write controller 31 controls the row decoder 12 and the column controller 13 to write data in the memory cells MC specified by the row addresses RA and column addresses CA.

The controller 15 (FIG. 1), particularly, for example, the read and write controller 31, also controls additional operations, which include precharging. Precharging refers to an operation to set the sense amplifier SA (for example, all the sense amplifier units SAU therein) in the column controller 13 back to an idle state. When the read and write controller 31 receives a command CMD instructing the precharging (i.e., a precharge command), it performs the precharging.

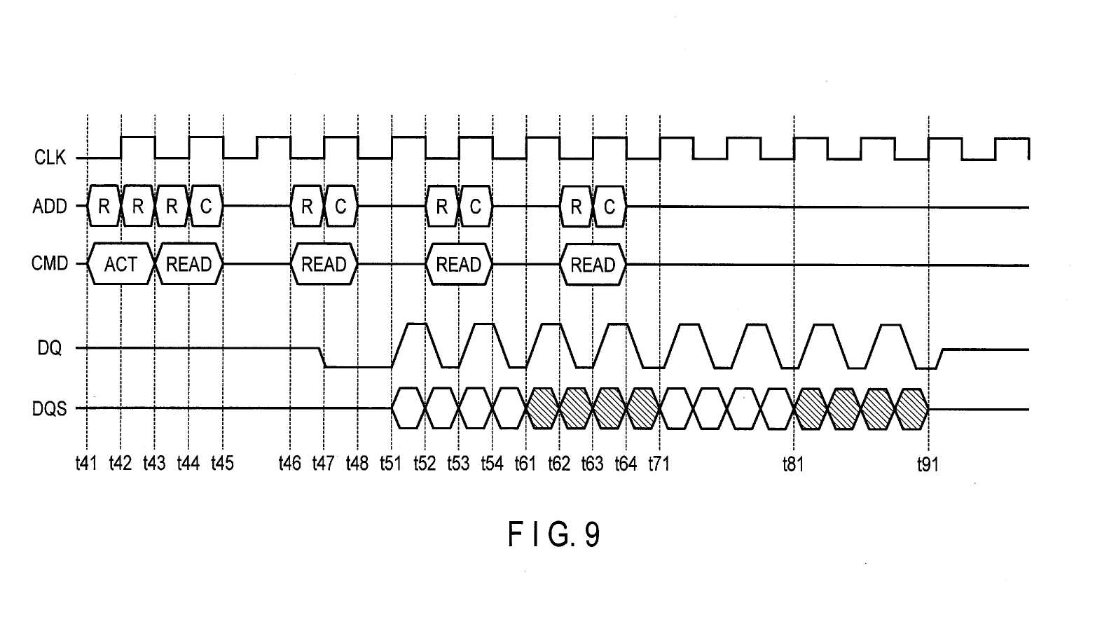

Referring to FIG. 9, data reads will now be described. FIG. 9 illustrates signals transmitted and received between the memory device and the memory controller over time during data reads in accordance with the fourth embodiment. The memory controller 2 keeps supplying the clock to the memory device 1 as illustrated in FIG. 9.

With the start of a data read, the memory controller 2 transmits an active command from time t41 to time t43. The active command is one of the commands CMD, and is illustrated as including the notation of “ACT” in FIG. 9. The active command has the same length as one cycle of the clock, for example. The active command is received by the controller 15. The controller 15 executes the process instructed by the active command.

The active command is first issued when the memory controller 2 makes an access to the memory device 1. The access includes reads and writes. The active command is issued by the memory controller 2 to specify the address of a row which it intends to access, for example. For example, all the sense amplifier units SAU are brought to the idle state, after a particular access to the memory device 1. The active command instructs activation of such sense amplifier units SAU in the idle state. Moreover, the active command instructs reading of data in all the memory cells MC coupled to a word line WL specified by a row address associated with that active command to respective bit lines coupled to those memory cells MC, and then to sense amplifier units SAU. The data in all the memory cells MC coupled to the word line WL specified by a row address is hereinafter referred to as “data of row address” specified, or selected. The data of row address is the same as the data in one page, for example. In accordance with the instruction by the active command, the controller 15 controls activation of the sense amplifier SA (or, the sense amplifier units SAU) and read of the data of a row address specified to the sense amplifier units SAU.

The active command is, for example, the active command defined for single data rate synchronous SDRAMs (SDR SDRAMs) and double data rate SDRAMs (DDR SDRAMs). The DDR SDRAMs include DDR2 SDRAMs, DDR3 SDRAMs, DDR4 SDRAMs, and DDR RAMS to be specified thereafter, as known by persons skilled in the art.

The row address of the data to be read to the sense amplifier units SAU by the active command is specified by the address signals ADD. The address signals ADD are transmitted in units of, for example, lengths of the half cycle of the clock. An address signal ADD may include a row address or a part thereof, or a column address or part thereof. An address signal ADD which includes a whole row address signal or part of a row address is illustrated as including the notation of “R”, and may be hereinafter referred to as a row address signal. Row address signals are transmitted in parallel with the active command, i.e., from time t41 to time t43. Therefore, two row address signals are transmitted while the active command is being transmitted. The two row address signals collectively include only a first section of the row address. Specifically, the two row address signals do not carry a whole row address even in conjunction, but only carry the first section collectively. The first section of the row address includes, for example, the section from the top of the row address specified using the active command, i.e., the row address of the memory cells MC storing data to be read to the sense amplifier SA.

The two row address signals do not have sufficient information to identify a row address. For this reason, the row address cannot be identified at this stage, and therefore the controller 15 does not (or, cannot) start transmission of the data of the row address to the sense amplifier units SAU. The address signals transmitted in parallel with the active command may be regarded as one address signal. Specifically, one address signal includes the first section of the row address. In this case, a row address signal has the same length as that of one cycle of the clock.

The memory controller 2 transmits a read command to the memory device 1 after the active command. For example, the memory controller 2 transmits the read command right after the active command from time t43 to time t45. The read command is one of the commands CMD, and is illustrated as including the notation of “READ” in FIG. 9.

The memory controller 2 further transmits two address signals ADD to the memory device 1 in parallel with the read command, i.e., from time t43 to time t45. Of the two address signals ADD, the address signal ADD transmitted first, i.e., that transmitted from time t43, includes the second section of the row address specified using the active command. The address signal ADD including the second section of the row address is also illustrated as including the notation of “R” in FIG. 9. The set of the first and second sections of the row address makes the whole row address specified using with the active command. For example, the second section is the remaining section following the first section of the row address.

By reception of the second section of the row address, the memory device 1 can now identify the row address specified by use of the active command. The row decoder 12 activates the word line WL specified by the row address. Moreover, in parallel with the activation of the specified word line WL, the controller 15 reads the data of the specified row address to the sense amplifier units SA. Specifically, when the controller 15 finishes the reception of the second section of the row address, it starts transmission of the data of the row address to the sense amplifier units SAU. The data of the row address read to the sense amplifier units SAU is kept stored in a buffer (for example, a page buffer) until the memory device 1 receives the next precharge command. The data stored in the sense amplifier units SAU until reception of the precharge command may be referred to as “the data of the selected row address.”

Of the two address signals ADD transmitted in parallel with the read command, that transmitted later, i.e., that transmitted from time t44, includes a column address. An address signal ADD including a column address is illustrated as including the notation of “C” in FIG. 9, and may be hereinafter referred to as a column address signal. The column address specifies part of the data of the selected row address. The column address is received by the read and write control 31.

The read and write controller 31 starts outputting from the memory device 1, of the data of the selected row address, the data of the column (or, section) specified by the column address. The controller 15, particularly, for example, the read and write controller 13, transmits the data of the section of the data of the selected row address specified by the column as the data DQ through control of the input and output controller 16 from time t51. Moreover, in parallel with this transmission of data, the controller 15 outputs the data strobe DQS from time t51.

The memory controller 2 also transmits another read command from time t46 to time t48. Time t46 follows time t45, and time t48 precedes time t51. The memory device 2 has not received an active command between time t45 and the read command from time t46. Therefore, the read command from time t46 results in a read of data from another column of the data of the selected row address. In order to execute such a read, the memory controller 2 first transmits a row address signal from time t46. This row address signal includes the second section of the row address signal, and includes the same information as the row address signal from time t44 to time t45. The row address is already selected, and therefore the row address signal from time t46 does not contribute to identification of the row address. The memory controller 2 transmits a column address signal from time t47 to time t48. This column address signal specifies the address of the column of the target of read from time t46.

After this, the same process as described so far is executed. Specifically, the memory device 1 outputs, from time t61 to time t71, the section of the data of the selected row address which is specified by the column address signal from time t47. Moreover, the memory device 1 receives another read command from time t52 to time t54, receives a row address signal from time t52 to time t53, and receives a column address signal from time t53 to t54. Time t52 to t54 is located between time t51 and time t61. The data specified by the column address signal from time t53 is output from the memory device 1 from time t71 to time t81.

The memory device 1 receives still another read command from t62 to t64, receives a row address signal from time t62 to time t63, and receives a column address signal from time t63 to time t64. Time t62 to t64 is located between time t61 and the time t71. The data specified by the column address signal from time t63 is output from the memory device 1 from time t81 to time t91.

The transmission of read data is completed, and therefore the memory device 1 makes the potential of the data strobe DQS the intermediate potential at time t91. Moreover, Since the reads from the row address selected were completed, the memory controller 2 transmits a precharge command (not shown) to the memory device 1 after time t91. The memory device 1 becomes able to accept a subsequent active command after it receives the precharge command and a time necessary for the precharge elapses.

Thus, the memory controller 2 transmits a row address signal and a column address signal in parallel with each read command after it transmits an active command. On the other hand, the memory device 1 requires specification of a section of a row address (a first section) by the address signal transmitted in parallel with the active command, and following specification of the remaining section (a second section) of the row address and a column address by the address signal transmitted in parallel with a subsequent read command. This contrasts with the features of DRAMs. In DRAMs, the notification of a whole to-be-specified row address is completed by the address signal transmitted in parallel with the active command, and an address signal transmitted in parallel with a read command only contains a column address. However, in DRAMs, time tRCD necessary for the DRAMs to be ready to accept a subsequent command (i.e., a read command) after the active command is defined. tRCD is referred to as a row-to-column delay. In contrast, the memory device 1 can receive the following command (i.e., a read command) immediately after reception of the active command, and therefore tRCD is not defined for the memory device 1.

As described, the memory device 1 of the fourth embodiment requires specification of a section of a row address by the address signal transmitted in parallel with the active command, and following specification of the remaining section of the row address and a column address by the address signal transmitted in parallel with a subsequent read command. Specifically, the memory device 1 receives a section of a row address in parallel with the active command, and, in parallel with a subsequent read command, receives the remaining section of the row address and a column address. This is useful when the memory device 1 has a long row address, for example. Specifically, even when an address signal parallel to the active signal does not have a length sufficient to transmit a whole row address, transmission of a section of the row address in parallel with the read command allows the memory device to receive the row address. In particular, the fourth embodiment is useful when the memory device should be designed to be used in accordance with a particular specification but a period for transmitting a row address in accordance with that specification does not have a length sufficient for the memory device 1 to receive the row address.

### Fifth Embodiment

The fifth embodiment is similar to the fourth embodiment, and relates to rules on transmission of commands between the memory device 1 and the memory controller 2, and transmission of commands and address signals for data writes. The memory device 1 is any memory device other than a DRAM, and is a nonvolatile memory device. The memory device 1 of the fifth embodiment has the same functional blocks as those in the fourth embodiment.

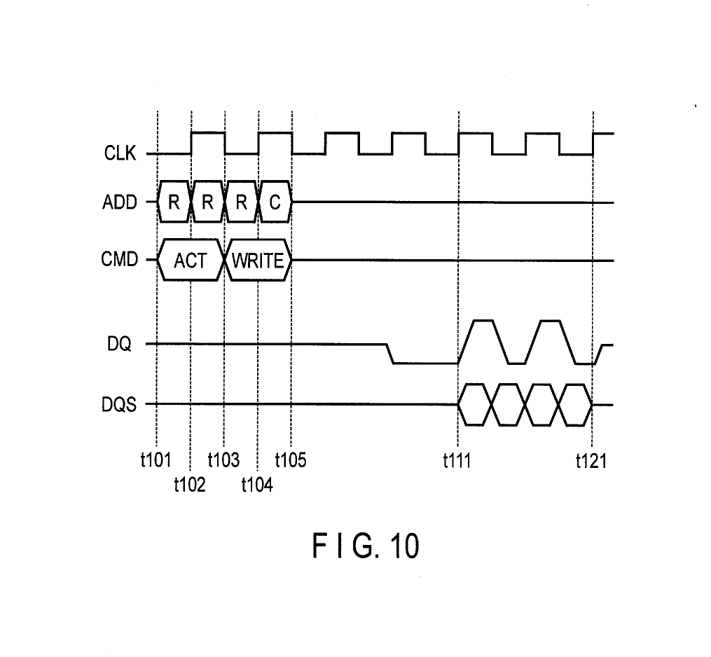

FIG. 10 illustrates signals transmitted and received between the memory device and the memory controller over time during a data write in accordance with the fifth embodiment. As in the fourth embodiment, the memory controller 2 transmits an active command and two address signals ADD from time t101 to time t103. These two address signals ADD are row address signals, and include the first section of the row address, which will be accessed.

The memory controller 2 transmits a write command after the active command from time t103 to time t105. The write command is illustrated as including the notation of “WRITE” in FIG. 10. The memory controller 2 further transmits two address signals ADD to the memory device 1 in parallel with the write command from time t103 to time t105. Of the two address signals ADD, that transmitted first, i.e., transmitted from time t103, is a row address signal, and includes the second section of the row address specified using the active command. By reception of the second section of the row address, the memory device 1 can now identify the row address specified using the active command. Of the two address signals ADD transmitted in parallel with the write command, that transmitted later, i.e., transmitted from time t104, is a column address signal. The reception of the whole row address and the column address allows the memory cells MC in which data will be written to be specified.

The memory controller 2 transmits write data as the data DQ to the memory device 1 after it transmits the write command and a certain period elapses. The length of this period is determined in accordance with the properties of the memory device 1, and is determined in accordance, at least in part, with execution or non-execution of error correction by the memory device 1. The memory controller 2 also transmits the data strobe DQS to the memory device 1 in parallel with the write command. When the memory controller 2 is to perform an additional write to the selected row, it transmits another write command (not shown) to the memory device 1. Whenever the memory controller 2 transmits a write address, it transmits two address signals in parallel with that write address. Each first address signal is a row address signal, and includes the same values as the row address signal transmitted first after an active command. Each second address signal is a column address signal. After a write is completed, the memory controller 2 transmits a precharge command (not shown).

As described above, the memory device 1 of the fifth embodiment requires specification of a section of a row address by the address signal transmitted in parallel with the active command, and following specification of the remaining section of the row address and a column address by the address signal transmitted in parallel with a subsequent write command. For this reason, the same advantages as those the fourth embodiment can be obtained also for writes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
memory elements; and
a controller which executes a process including a first section and a second section in response to a refresh command, detects an error of data stored in the memory elements in the first section, and writes correct data in a memory element storing data with the detected error in a second section, the second section being variable in accordance with a time to write the correct data.

2. The device of claim 1, wherein:
the controller identifies a memory element storing data with the detected data and writes correct data in the identified memory element.

3. The device of claim 1, wherein:
the controller detects an error in all predetermined sized segments of received data in units of the segments in the first section, and identifies a memory element storing data with the detected error and writes correct data in the identified memory element in the second section.

4. The device of claim 3, wherein:
the controller comprises a register storing information for identifying memory elements of the memory elements storing an error-corrected segment.

5. The device of claim 1, wherein:
the controller outputs no data stored in the memory elements to outside the memory device in the first section.

6. The device of claim 1, wherein:
the memory device further comprises second memory elements different from the memory elements; and
the controller executes error detection and writing of correct data to the second memory elements in response to another refresh command.

7. The device of claim 1, wherein
the controller outputs a signal indicating that the memory device accepts no command to outside the memory device from a start to an end of the second section.

8. The device of claim 7, wherein:
in response to a read command, the controller corrects an error of data stored in the memory elements, outputs data with the error corrected to outside the memory device, and executes no operation for writing back the error-corrected data to the memory elements.

9. The device of claim 1, wherein:
the memory elements store data in a non-volatile manner.

10. The device of claim 1, wherein:
each of the memory elements comprises a first magnetic layer with variable magnetization, a second magnetic layer with fixed magnetization, and a nonmagnetic layer between the first and second magnetic layers.

11. A memory device comprising:
memory elements; and
a controller which, in response to a refresh command, detects an error of data stored in the memory elements, writes correct data in a memory element storing data with the detected error, and outputs no data stored in the memory elements to outside the memory device.

12. The device of claim 11, wherein:
the controller:
detects an error in all predetermined sized segments of received data in units of the segments, and
whenever a segment including an error is detected, after the detection writes correct data in a memory element storing data with the detected error.

13. The device of claim 11, wherein:
the memory device further comprises second memory elements different from the memory elements; and
the controller executes error detection and writing of correct data to the second memory elements in response to another refresh command.

14. The device of claim 11, wherein:
in response to a read command, the controller corrects an error of data stored in the memory elements, outputs data with the error corrected to outside the memory device, and executes no operation for writing back the error-corrected data to the memory elements.

15. The device of claim 11, wherein:
the memory elements store data in a non-volatile manner.

16. The device of claim 11, wherein:
each of the memory elements comprises a first magnetic layer with variable magnetization, a second magnetic layer with fixed magnetization, and a nonmagnetic layer between the first and second magnetic layers.

17. A memory device comprising:
memory elements; and
a controller, which executes a process including a first section and a second section in response to a read command, corrects an error of data stored in the memory elements and outputs data with the error corrected to outside the memory device in the first section, and writes correct data in a memory element storing data with the error corrected in a second section, the second section being variable in accordance with a time to write the correct data, and the controller outputting a signal indicating that the memory device accepts no command to outside the memory device from a start to an end of the second section.

18. The device of claim 17, wherein:
the controller detects an error in all predetermined sized segments of received data in units of the segments in the first section, and identifies a memory element storing the detected data with an error and writes correct data in the identified memory element in the second section.

19. The device of claim 17, wherein:
the memory elements store data in a non-volatile manner.

20. The device of claim 17, wherein:
each of the memory elements comprises a first magnetic layer with variable magnetization, a second magnetic layer with fixed magnetization, and a nonmagnetic layer between the first and second magnetic layers.

21. A memory device comprising:
memory elements; and
a controller which receives a first command in parallel with first address information, and accepts a read command or a write command following the first command.

22. The device of claim 21, wherein:
the controller, in response to second address information received in parallel with the read or write command, reads data from first memory elements of the memory elements identified by the first and second address information or writes data in at least one of the first memory elements.

23. The device of claim 22, wherein:
the second address information includes a first section and a second section,
the controller identifies a row address from a set of the first address information and the first section of the second address information, and
the row address identifies the first memory elements.

24. The device of claim 23, wherein:
the controller starts reading of data from the first memory elements in response to reception of the second section of the second address information.

25. The device of claim 24, wherein:
the first memory elements are coupled to a first word line, and
the row address identifies the first word line.

26. The device of claim 24, wherein:
the second section of the second address information identifies a subset of the first memory elements.

27. The device of claim 21, wherein:
the memory device further comprises a sense amplifier, and
the first command instructs activation of the sense amplifier.
